(19) United States
(12) Patent Application Publication
(10) Pub. No.: US 2025/0369097 A1
(43) Pub. Date: Dec. 4, 2025

(54) METHOD FOR SELECTIVE DEPOSITION OF METAL LAYER

(71) Applicants: Samsung Electronics Co., Ltd., Suwon-si (KR); University-Industry Cooperation Group Of Kyung Hee University, Yongin-si (KR)

(72) Inventors: Haeryong KIM, Suwon-si (KR); Woojin JEON, Yongin-si (KR); Byunghoon NA, Suwon-si (KR); Woonghyeon PARK, Suwon-si (KR); Jeonghyeon PARK, Yongin-si (KR); Jaeho LEE, Suwon-si (KR); Yoonah CHOI, Yongin-si (KR)

(73) Assignees: Samsung Electronics Co., Ltd., Suwon-si (KR); University-Industry Cooperation Group Of Kyung Hee University, Yongin-si (KR)

(21) Appl. No.: 19/021,901

(22) Filed: Jan. 15, 2025

(30) Foreign Application Priority Data
Jun. 4, 2024 (KR) 10-2024-0073185

(51) Int. Cl. C23C 16/04; C07F 17/02; C23C 16/02; C23C 16/18; C23C 16/44; C23C 16/455; C23C 16/56

(52) U.S. Cl. CPC C23C 16/04; C07F 17/02; C23C 16/02; C23C 16/18; C23C 16/4408; C23C 16/45553; C23C 16/56

(57) ABSTRACT

A method for selective deposition of a metal layer may include providing a substrate including a first region and a second region, and selectively forming a first metal layer on the first region of the substrate and forming a second metal layer on the second region of the substrate. The first region of the substrate may include a transition metal or a transition metal nitride. The second region of the substrate may include silicon.

### CROSS-REFERENCE TO RELATED APPLICATION

This application is based on and claims priority under 35 USC § 119 to Korean Patent Application No. 10-2024-0073185, filed on Jun. 4, 2024, in the Korean Intellectual Property Office, the disclosure of which is incorporated by reference herein in its entirety.

### BACKGROUND

### 1. Field

The disclosure relates to a method for selective deposition of a metal layer.

### 2. Description of the Related Art

As integration in DRAM and V-NAND advances to enhance device integration density, process miniaturization is progressing. The miniaturization of line widths increases the difficulty of patterning processes such as lithography and etching, and it may be advantageous to perform area-selective deposition (ASD), which selectively deposits material only in the required areas during the deposition stage.

The performance of an area-selective deposition process may be expressed by the selectivity, which indicates the difference in deposition between desired and undesired areas, and in order to improve the efficiency of an area-selective deposition process, it may be advantageous to find ways to increase selectivity.

### SUMMARY

Provided is a method for selective deposition of a metal layer with increased selectivity.

Additional aspects will be set forth in part in the description which follows and, in part, will be apparent from the description, or may be learned by practice of the presented embodiments of the disclosure.

According to an embodiment of the disclosure, a method for selective deposition of a metal layer may include preparing a substrate including a first region and a second region; and selectively forming a first metal layer on the first region of the substrate and forming a second metal layer on the second region of the substrate. The first region of the substrate may include a transition metal or a transition metal nitride, and the second region of the substrate may include silicon.

In some embodiments, the method for selective deposition of the metal layer may further include forming a third metal layer by etching the first metal layer and etching and removing the second metal layer.

In some embodiments, the forming the first metal layer on the first region of the substrate and the forming the second metal layer on the second region of the substrate may be performed in a plurality of cycles, and each cycle of the plurality of cycles may include supplying a precursor to the substrate, a first purge to remove excess of the precursor, stabilizing reactants, supplying the reactants to the substrate, and a second purge to remove excess of the reactants.

In some embodiments, the precursor may include a cobalt compound of Formula (1).

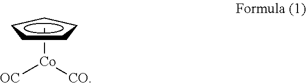

In some embodiments, the reactants may include N₂ and NH₃.

In some embodiments, the precursor may include a cobalt compound of the following Formula (2).

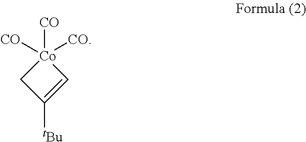

In some embodiments, the reactants may include Ar and H₂.

In some embodiments, the reactants may include NH₃, H₂, N₂+H₂, N₂/H₂, N₂+NH₃+H₂, N₂/NH₃/H₂ NH₃+H₂+Ar, Ar+NH₃, or Ar+H₂.

In some embodiments, the may method may further include plasma pre-treating the substrate prior to the preparing the substrate including the first region and the second region.

In some embodiments, the plasma pre-treating the substrate may be performed using a plasma generated using NH₃, H₂, N₂+H₂, N₂/H₂, N₂+NH₃+H₂, N₂/NH₃/H₂ NH₃+H₂+Ar, Ar+NH₃, or Ar+H₂.

In some embodiments, the first region of the substrate may include the transition metal and the transition metal may include titanium (Ti), zirconium (Zr), hafnium (Hf), vanadium (V), niobium (Nb), tantalum (Ta), molybdenum (Mo), tungsten (W), and technetium (Tc), rhenium (Re), rhodium (Rh), iridium (Ir), nickel (Ni), palladium (Pd), platinum (Pt), zinc (Zn), chromium (Cr), or tin (Sn).

In some embodiments, the first region of the substrate may include the transition metal nitride and the transition metal nitride may include titanium nitride, zirconium nitride, hafnium nitride, vanadium nitride, niobium nitride, tantalum nitride, molybdenum nitride, tungsten nitride, technetium nitride, rhenium nitride, rhodium nitride, iridium nitride, nickel nitride, and palladium nitride, platinum nitride, zinc nitride, chromium nitride, or tin nitride.

According to an embodiment of the disclosure, a method for selective deposition of a metal layer may include preparing a substrate including a first region and a second region; selectively forming a metal layer on the first region of the substrate; and etching a portion of the metal layer. The first region of the substrate may include a transition metal or a transition metal nitride, and the second region of the substrate may include silicon. The selectively forming the metal layer on the first region of the substrate and the etching the portion of the metal layer may be repeated.

In some embodiments, the forming the metal layer on the first region of the substrate may be performed in a plurality of cycles. Each of the plurality of cycles may include supplying a precursor to the substrate, a first purge to remove excess of the precursor, stabilizing reactants, supplying the reactants to the substrate, and a second purge to remove excess of the reactants.

In some embodiments, the precursor may include a cobalt compound of the following Formula (1).

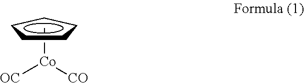

In some embodiments, the reactants may include N₂ and NH₃.

In some embodiments, the precursor may include a cobalt compound of Formula (2).

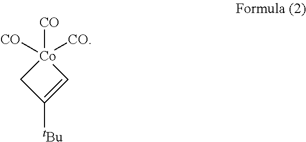

In some embodiments, the reactants may include Ar and H₂.

In some embodiments, the method for selective deposition of the metal layer may further include plasma pre-treating the substrate prior to the preparing the substrate including the first region and the second region.

In some embodiments, the plasma pre-treating the substrate may be performed using a plasma generated using NH₃, H₂, N₂+H₂, N₂/H₂, N₂+NH₃+H₂, N₂/NH₃/H₂ NH₃+H₂+Ar, Ar+NH₃, or Ar+H₂.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart schematically showing a method for selective deposition of a metal layer, according to an embodiment;

FIGS. 2A to 2D are cross-sectional views showing a method for selective deposition of a metal layer, according to an embodiment;

FIG. 3 is a flowchart illustrating a method of forming a metal layer by an atomic layer deposition process, according to an example embodiment;

FIG. 4 is a graph showing a metal layer deposition cycle according to an embodiment;

FIGS. 5A and 5B are graphs showing plasma pretreatment according to an embodiment;

FIGS. 6A and 6B are graphs showing changes in selectivity of metal layers, according to an embodiment; and

FIG. 7 is a flowchart illustrating a method of forming a metal layer by an atomic layer deposition process, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a method for selective deposition of a metal layer according to various embodiments will be described in detail with reference to the attached drawings. In the following drawings, the same reference numerals refer to the same components, and the size of each component in the drawings may be exaggerated for clarity and convenience of explanation. Additionally, the embodiments described below are merely illustrative, and various modifications are possible from these embodiments.

Hereinafter, the term “above” or “on” may include not only what is directly on in a contact matter, but also what is above in a non-contact manner. Singular expressions include plural expressions unless the context clearly dictates otherwise. Additionally, when a part “comprises” a certain component, this means that it may further include other components rather than excluding other components, unless specifically stated to the contrary.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The use of the term “the” and similar referential terms may refer to both the singular and the plural. Unless the order of the steps constituting the method is clearly stated or stated to the contrary, these steps may be performed in any appropriate order and are not necessarily limited to the order described.

The connections or connection members of lines between components shown in the drawings may show functional connections and/or physical or circuit connections, and in actual devices, various functional connections, physical connections, and or may be represented as circuit connections.

The use of all examples or illustrative terms is simply for explaining technical ideas in detail, and the scope is not limited by these examples or illustrative terms unless limited by the claims.

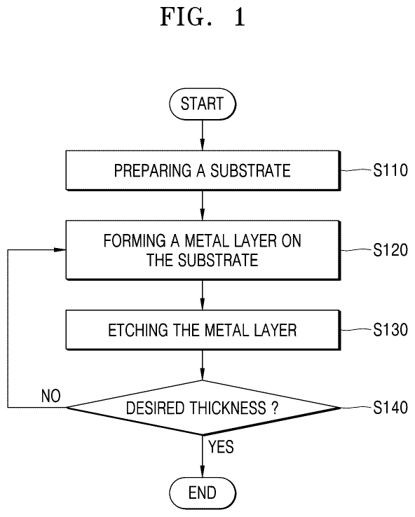

FIG. 1 is a flowchart schematically showing a method for selective deposition of a metal layer according to an example embodiment.

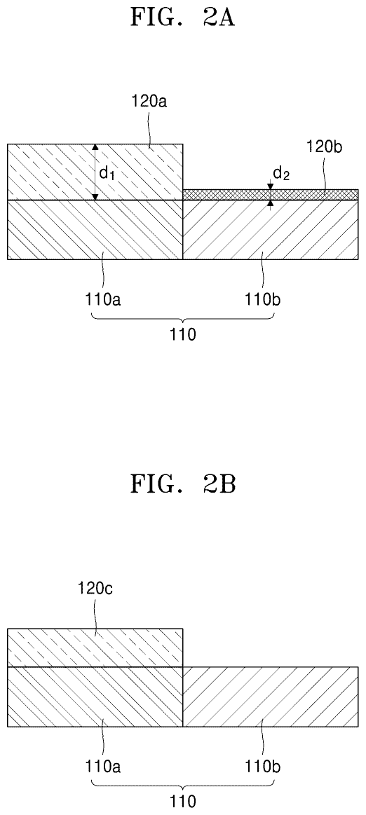

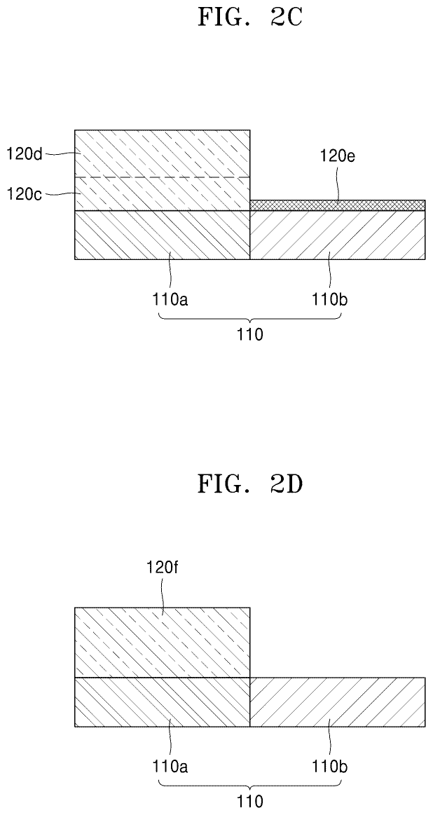

FIGS. 2A to 2D are cross-sectional views showing a method for selective deposition of a metal layer according to an example embodiment.

Referring to FIGS. 1 and 2A, a substrate 110 may be prepared in a reaction space (S110). The reaction space may include, for example, a reaction chamber.

The substrate 110 may include a first region 110a and a second region 110b. The first region 110a of the substrate 110 may include a transition metal or a transition metal nitride.

The transition metal may include, for example, titanium (Ti), zirconium (Zr), hafnium (Hf), vanadium (V), niobium (Nb), tantalum (Ta), molybdenum (Mo), and tungsten (W), technetium (Tc), rhenium (Re), rhodium (Rh), iridium (Ir), nickel (Ni), palladium (Pd), platinum (Pt), zinc (Zn), chromium (Cr), or tin (Sn).

The transition metal nitride may include, for example, titanium nitride, zirconium nitride, hafnium nitride, vanadium nitride, niobium nitride, tantalum nitride, molybdenum nitride, tungsten nitride, technetium nitride, rhenium nitride, rhodium nitride, iridium nitride, and nickel nitride, palladium nitride, platinum nitride, zinc nitride, chromium nitride, or tin nitride.

The second region 110b of the substrate 110 may include silicon. The first region 110a and the second region 110b of the substrate 110 include different materials, enabling the area-selective deposition described below.

Next, a metal layer is selectively formed on the substrate 110 (S120). The method of forming the metal layer utilizes area-selective deposition.

The area-selective deposition method may include an atomic layer deposition (ALD) process.

Through the area-selective deposition method, a first metal layer 120a may be formed on the first region 110a of the substrate 110. When the substrate 110 undergoes plasma treatment with various plasma gases, due to the different chemical properties of the first region 110a and the second region 110b of the substrate 110, the precursor reacts only in a specific region among the first region 110a and the second region 110b or acts across the entire area, and consequently, the selectivity(S) may be increased or decreased, allowing the selectivity(S) to be adjusted as needed.

The process performance of the area-selective deposition method may be indicated by selectivity(S), which represents the difference in the degree of deposition in the desired area versus the undesired area. In FIG. 2A, the desired area may be the first region 110a of the substrate 110, and the undesired area may be the second region 110b of the substrate 110.

The selectivity(S), indicated by the thickness (d1) of the first metal layer 120a and the thickness (d2) of the second metal layer 120b in FIG. 2A, may be expressed by the following Equation (1).

$$S = \frac{d 1 - d 2}{d 1 + d 2} \qquad Equation ( 1 )$$

The fact that the metal layer is ‘selectively’ formed means that the metal layer is more preferentially formed on the first region 110a of the substrate 110 rather than on the surface of the second region 110b of the substrate 110. During the process of forming the first metal layer 120a on the first region 110a of the substrate 110, a second metal layer 120b may also be formed on the second region 110b of the substrate 110.

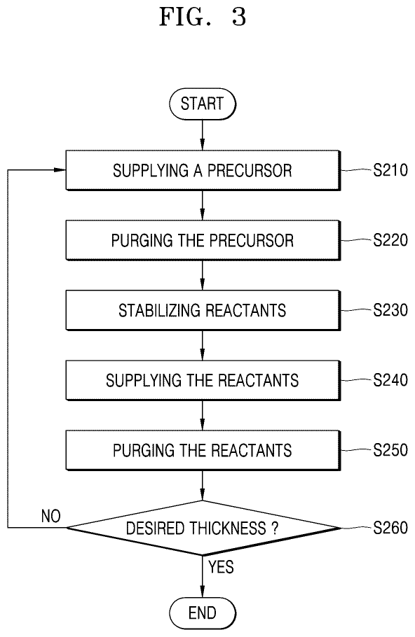

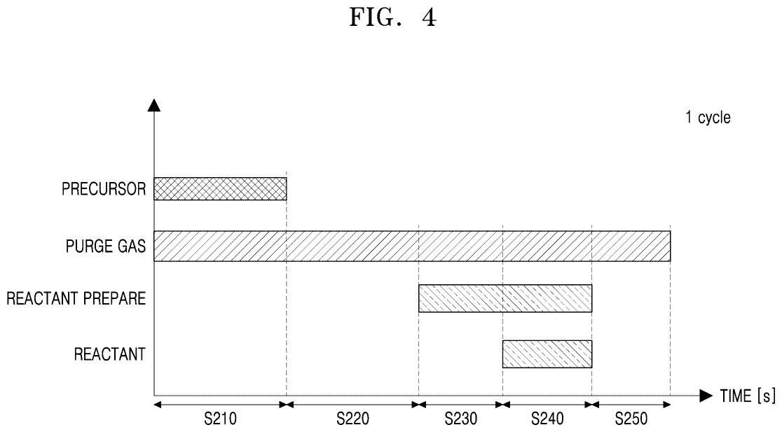

The selectively forming a metal layer on the substrate 110 (S120) may include supplying a precursor to the substrate 110, a first purge to remove excess precursor that did not participate in the reaction, stabilizing reactants, supplying the reactants to the substrate 110, and a second purge to remove excess reactants that did not participate in the reaction, as will be described later with reference to FIG. 3. The supplying a precursor to the substrate 110, the first purge to remove excess precursor that did not participate in the reaction, the stabilizing reactants, the supplying the reactants to the substrate 110, and the second purge to remove excess reactants that did not participate in the reaction may be defined as one cycle.

The selectively forming a metal layer on the substrate 110 (S120) may be repeatedly performed until a metal layer of the desired thickness is formed. That is, the selectively forming a metal layer on the substrate 110 (S120) may include a plurality of cycles.

Referring to FIGS. 1 and 2B, the first metal layer 120a and the second metal layer 120b are etched by the thickness of the second metal layer 120b (d2) formed on the second region 110b of the substrate 110 (S130). By etching the first metal layer 120a and the second metal layer 120b by the thickness of the second metal layer 120b (d2), the unnecessary second metal layer 120b formed on the second region 110b of the substrate 110 may be removed.

Referring to FIG. 1, FIG. 2C, and FIG. 2D, it is determined whether the thickness of the first metal layer 120a is the desired thickness, and if the thickness of the first metal layer 120a is less than the desired thickness, the forming a metal layer on the substrate 110 (S120) and etching the metal layer (S130) may be repeated (S140).

Specifically, after forming the first metal layer 120a on the first region 110a of the substrate 110 and forming the second metal layer 120b on the second region of the substrate, the first metal layer 120a is etched to form the third metal layer 120c, and the second metal layer 120b is etched and removed. The first metal layer 120a is etched by the thickness of the second metal layer 120b. That is, the thickness of the third metal layer 120c is the value obtained by subtracting the thickness of the second metal layer 120b from the thickness of the first metal layer 120a (d1). Through this process, a metal layer may be simply formed without a patterning process.

Subsequently, a fourth metal layer 120d is formed on the third metal layer 120c, and a fifth metal layer 120e is formed on the second region 110b of the substrate. Afterward, a part of the fourth metal layer 120d is etched to form a sixth metal layer 120f, and the fifth metal layer 120e is etched and removed. The thickness of the sixth metal layer 120f is obtained by subtracting the thickness of the fifth metal layer 120e from the sum of the thicknesses of the third metal layer 120c and the fourth metal layer 120d. By repeating this process, a metal layer of desired thickness may be formed.

The area-selective deposition method according to an example embodiment may increase the efficiency of selective deposition as the selectivity increases, and it allows for the simpler formation of a metal layer without a patterning process.

FIG. 3 is a flowchart illustrating a method of forming a metal layer by an atomic layer deposition process according to an example embodiment.

FIG. 4 is a graph showing the metal layer deposition cycle according to an example embodiment.

Referring to FIGS. 3 and 4, a precursor may be supplied on the substrate (S210). The precursor may include a cobalt compound of Formula (1) or a cobalt compound of Formula (2). The cobalt compound of formula (1) and the cobalt compound of formula (2) have a monovalent oxidation number of cobalt.

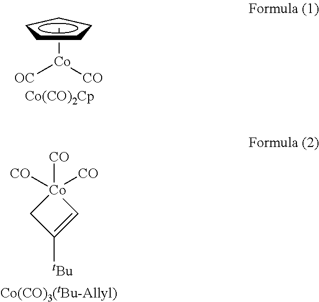

The precursor supplied on the substrate may be chemically adsorbed onto the substrate. Additionally, excess precursor may be physically adsorbed on the substrate. The supplying the precursor onto the substrate (S210) may be maintained for, for example, about 1 second to about 20 seconds. For example, the supplying the precursor onto the substrate (S210) may be maintained for 15 seconds.

A first purge may be performed to remove excess precursors that did not participate in the reaction (S220). For this purpose, a purge gas may be supplied on the substrate. The purge gas may remove the physically adsorbed precursor. For example, by injecting Ar gas or N₂ gas into the reaction chamber, the excess precursor and reaction by-products inside the reaction chamber may be removed.

The first purge (S220) may be maintained for, for example, about 1 second to about 20 seconds. The first purge (S220) may be maintained for, for example, 15 seconds. The purge gas may always be present in the metal layer deposition cycle.

The reactants may be stabilized before being supplied onto the substrate to react with the precursor (S230). The stabilizing reactants (S230) may be maintained for, for example, about 1 second to about 10 seconds. The stabilizing reactants (S230) may be maintained for, for example, 5 seconds.

Subsequently, the reactants may be supplied onto the substrate to react with the precursor (S240). The reactants may react with the precursor to form a metal layer. The reactants may include, for example, NH₃, H₂, N₂+H₂, N₂/H₂, N₂+NH₃+H₂, N₂/NH₃/H₂ NH₃+H₂+Ar, Ar+NH₃, or Ar+H₂. The supplying the reactants (S240) may be maintained for, for example, about 1 second to about 20 seconds. The supplying the reactants (S240) may be maintained for, for example, 12 seconds.

The reactants may be determined to have a more optimal selectivity depending on the precursor. For example, when the precursor contains Co(CO)₂Cp of the Formula (1), the reactants may include a mixed gas of N₂ and NH₃. In this case, the NH₃ ratio may be about 10% to about 50%. For example, when the precursor includes Co(CO)₃(^{t}Bu-Allyl) of Formula (2), the reactants may include a mixed gas of Ar and H₂. In this case, the H₂ ratio may be about 5% to about 20%.

A second purge to remove excess reactants that did not participate in the reaction and by-products generated by the reaction from the reaction chamber may be performed (S250). The purge gas may include, for example, Ar gas or N₂ gas. The second purge (S250) may be maintained for, for example, about 1 second to about 20 seconds. The second purge (S250) may be maintained for, for example, 15 seconds.

It is determined whether the thickness of the metal layer is the desired thickness (S260), and if the thickness of the metal layer is less than the desired thickness, the operations described above may be repeated. The thickness of the metal layer formed through the above steps may be, for example, 30 Å or less.

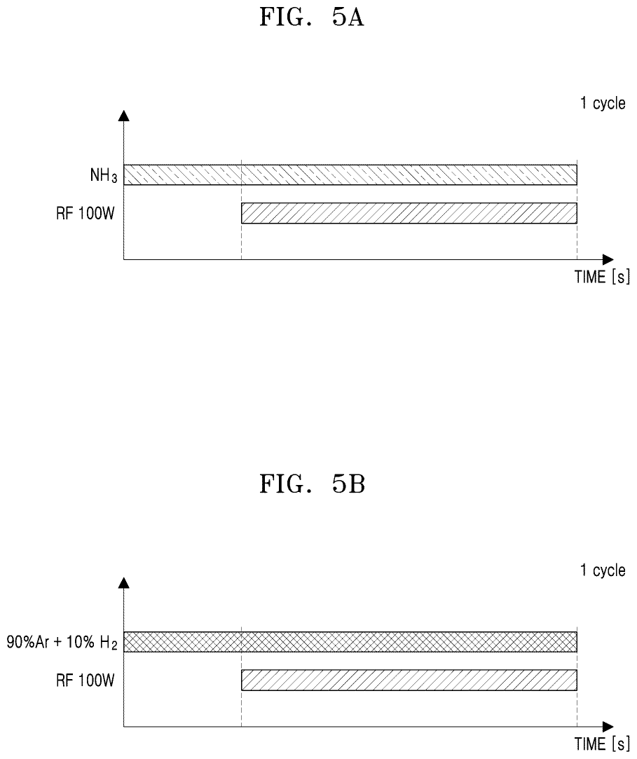

FIGS. 5A and 5B are graphs showing plasma pretreatment according to an example embodiment.

Referring to FIG. 5A, the substrate may be surface-treated using NH₃. At this time, the RF plasma power may be 100 W.

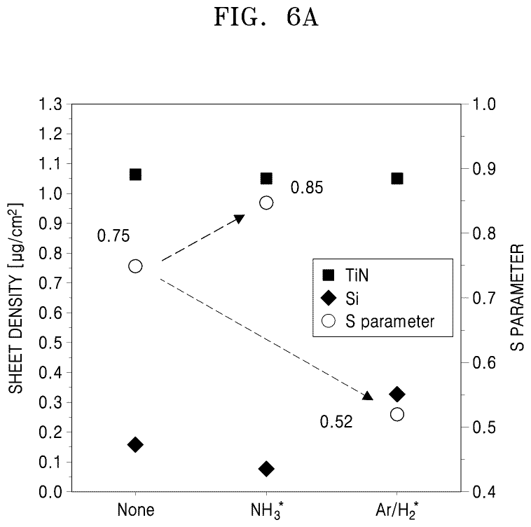

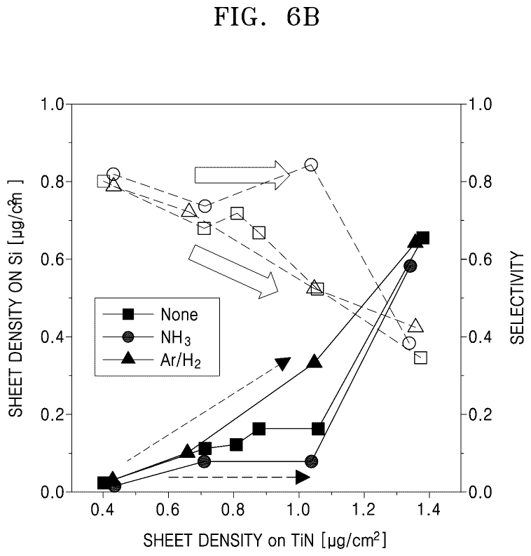

After supplying NH₃, the substrate may be treated with an RF plasma power of 100 W after a certain period. The selectivity of the metal layer formed by the plasma treatment will be described later with reference to FIGS. 6A and 6B.

Referring to FIG. 5B, the substrate may be surface-treated using Ar and H₂. The ratio of Ar to H₂ may be about 9:1. At this time, the RF plasma power may be 100 W.

After supplying Ar and H₂, the substrate may be treated with an RF plasma power of 100 W after a certain period. The selectivity ratio of the metal layer formed by the plasma treatment will be described later with reference to FIGS. 6A and 6B.

FIGS. 6A and 6B are graphs showing changes in the selectivity of the metal layers according to an embodiment.

In the metal deposition method according to an embodiment, 20 cycles were carried out using a Co(CO)₂Cp precursor on a substrate with TiN in the first region and Si in the second region at a process temperature of 180° C.

Referring to FIG. 6A, when the substrate is not plasma-treated, the amount of cobalt metal layer deposited on the first region containing TIN is 1.06 μg/cm², while the amount of cobalt metal layer deposited on the second region containing Si is 0.16 μg/cm² due to the relatively limited and/or suppressed adsorption of the Co(CO)₂Cp precursor. Consequently, the selectivity was 0.75. The selectivity is labeled as S parameter on FIG. 6A.

Next, when the substrate is plasma-treated with Ar+H₂, the amount of cobalt metal layer deposited on the first region containing TiN remained unchanged at 1.05 μg/cm², but the amount of cobalt metal layer deposited on the second region containing Si increased to 0.33 μg/cm² due to the increased —H* surface. Consequently, the selectivity decreased to 0.52.

Additionally, when the substrate is plasma-treated with NH₃, the amount of cobalt metal layer deposited on the first region containing TiN remained unchanged at 1.05 μg/cm², but the amount of cobalt metal layer deposited on the second region containing Si decreased to 0.08 μg/cm² due to the mixed —NHₓ* surface and —H* surface. Consequently, the selectivity increased to 0.85.

Referring to FIGS. 6A and 6B, when the substrate is plasma-treated with Ar+H₂, the amount of cobalt metal layer deposited on the first region containing TiN increases to about 1.05 μg/cm², while the amount of cobalt metal layer deposited on the second region containing Si increases to 0.33 μg/cm².

In contrast, when the substrate is plasma-treated with NH₃, even if the amount of cobalt metal layer deposited on the first region containing TiN increases to about 1.05 μg/cm², the amount of precursor deposited on the second region containing Si remains largely unchanged at 0.08 μg/cm².

Therefore, when the substrate is plasma-treated with NH₃, the —NHₓ* surface and —H* surface are mixed in the second region of the substrate containing Si, limiting and/or suppressing the deposition of the cobalt metal layer, and allowing the cobalt metal layer to be selectively formed on the first region of the substrate.

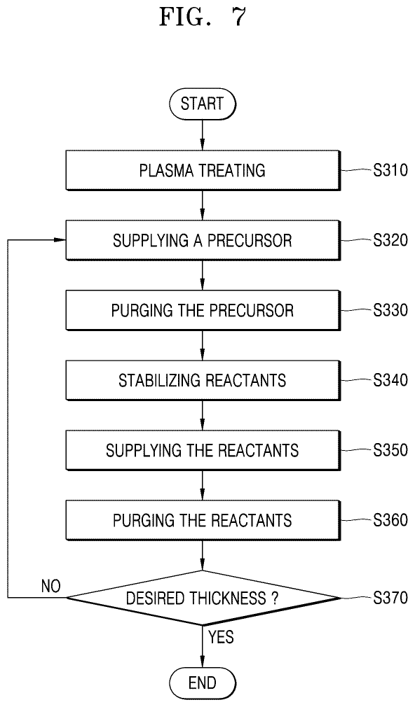

FIG. 7 is a flowchart illustrating a method of forming a metal layer by an atomic layer deposition process according to an example embodiment.

Referring to FIG. 7, the substrate may be plasma-treated before supplying the precursor onto the substrate (S310). The plasma may utilize plasma of reactant gas used in the deposition process. The plasma may include, for example, NH₃, H₂, N₂+H₂, N₂/H₂, N₂+NH₃+H₂, N₂/NH₃/H₂ NH₃+H₂+Ar, Ar+NH₃, or Ar+H₂. In other words, the plasma may be generated using NH₃, H₂, N₂+H₂, N₂/H₂, N₂+NH₃+H₂, N₂/NH₃/H₂ NH₃+H₂+Ar, Ar+NH₃, or Ar+H₂.

By plasma-treating the substrate, the deposition of the metal layer in the second region containing silicon is delayed while the metal layer is deposited to the same thickness in the first region containing the transition metal or the transition metal nitride. This enables the selective deposition of the metal layer.

Subsequently, the precursor is supplied onto the substrate (S320), purge gas is supplied to the substrate (S330), reactant is stabilized (S340), the reactants may be supplied to the substrate (S350), and purge gas may be supplied to the substrate (S360). Operations S320 to S360 may be the same as operations S210 to S250 described with reference to FIG. 3. The method of forming the metal layer by an atomic layer deposition process in FIG. 7 may be the same as the method of forming the metal layer by an atomic layer deposition process in FIG. 3, except that it further includes the plasma-treating the substrate before supplying the precursor to the substrate (S310).

According to the selective deposition method of the metal layer disclosed herein, the efficiency of selective deposition may be increased as the selectivity increases, allowing for the simpler formation of a metal layer without a patterning process. Although the layer has been described with reference to the embodiments illustrated in the drawings, these are merely examples, and those skilled in the art will understand that various modifications and other equivalent embodiments are possible. Therefore, the disclosed embodiments should be considered in a descriptive sense, not a limiting sense. The scope of the rights is indicated by the appended claims, and all differences within the equivalent scope should be construed as being included in the scope of rights.

The method for selective deposition of a metal layer according to an example embodiment may increase the efficiency of selective deposition as the selectivity increases.

The method for selective deposition of a metal layer according to an example embodiment allows for the simpler formation of a metal layer without the need for a patterning process.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method for selective deposition of a metal layer, comprising:
preparing a substrate including a first region and a second region; and
selectively forming a first metal layer on the first region of the substrate and forming a second metal layer on the second region of the substrate, wherein
the first region of the substrate includes a transition metal or a transition metal nitride, and
the second region of the substrate includes silicon.

2. The method of claim 1, further comprising:
forming a third metal layer by etching the first metal layer and etching and removing the second metal layer.

3. The method of claim 1,
wherein the forming the first metal layer on the first region of the substrate and the forming the second metal layer on the second region of the substrate is performed in a plurality of cycles,
each cycle of the plurality of cycles includes supplying a precursor to the substrate, a first purge to remove excess of the precursor, stabilizing reactants, supplying the reactants to the substrate, and a second purge to remove excess of the reactants.

4. The method of claim 3,
wherein the precursor includes a cobalt compound of Formula (1):

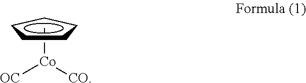

5. The method of claim 4,
wherein the reactants include N₂ and NH₃.

6. The method of claim 3,
wherein the precursor includes a cobalt compound of Formula (2):

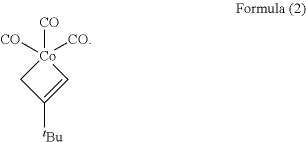

7. The method of claim 6,
wherein the reactants include Ar and H₂.

8. The method of claim 3,
wherein the reactants include NH₃, H₂, N₂+H₂, N₂/H₂, N₂+NH₃+H₂, N₂/NH₃/H₂ NH₃+H₂+Ar, Ar+NH₃, or Ar+H₂.

9. The method of claim 1, further comprising:
plasma pre-treating the substrate prior to the preparing the substrate including the first region and the second region.

10. The method of claim 9,
wherein the plasma pre-treating the substrate is performed using a plasma generated using NH₃, H₂, N₂+H₂, N₂/H₂, N₂+NH₃+H₂, N₂/NH₃/H₂ NH₃+H₂+Ar, Ar+NH₃, or Ar+H₂.

11. The method of claim 1,
wherein the first region of the substrate includes the transition metal, and
the transition metal includes titanium (Ti), zirconium (Zr), hafnium (Hf), vanadium (V), niobium (Nb), tantalum (Ta), molybdenum (Mo), tungsten (W), technetium (Tc), rhenium (Re), rhodium (Rh), iridium (Ir), nickel (Ni), palladium (Pd), platinum (Pt), zinc (Zn), chromium (Cr), or tin (Sn).

12. The method of claim 1,
wherein first region of the substrate includes the transition metal nitride, and the transition metal nitride includes titanium nitride, zirconium nitride, hafnium nitride, vanadium nitride, niobium nitride, tantalum nitride, molybdenum nitride, tungsten nitride, technetium nitride, rhenium nitride, rhodium nitride, iridium nitride, nickel nitride, palladium nitride, platinum nitride, zinc nitride, chromium nitride or tin nitride.

13. A method for selective deposition of a metal layer, comprising:
preparing a substrate including a first region and a second region;
selectively forming a metal layer on the first region of the substrate; and
etching a portion of the metal layer, wherein
the first region of the substrate includes a transition metal or a transition metal nitride,
the second region of the substrate includes silicon, and
the selectively forming the metal layer on the first region of the substrate and the etching of the portion of the metal layer are repeated.

14. The method of claim 13,
wherein the selective forming the metal layer on the first region of the substrate is performed in a plurality of cycles,
each cycle of the plurality of cycles includes supplying a precursor to the substrate, a first purge to remove excess of the precursor, stabilizing reactants, supplying the reactants to the substrate, and a second purge to remove excess of the reactants.

15. The method of claim 14,
wherein the precursor includes a cobalt compound of Formula (1).

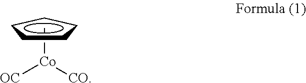

16. The method of claim 15,
wherein the reactants include N₂ and NH₃.

17. The method of claim 14,
wherein the precursor includes a cobalt compound of Formula (2).

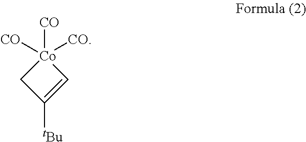

18. The method of claim 17,
wherein the reactants include Ar and H₂.

19. The method of claim 13, further comprising:
plasma pre-treating the substrate prior to the preparing the substrate including the first region and the second region.

20. The method of claim 19,
wherein the plasma pre-treating the substrate is performed using a plasma generated using NH₃, H₂, N₂+H₂, N₂/H₂, N₂+NH₃+H₂, N₂/NH₃/H₂ NH₃+H₂+Ar, Ar+NH₃, or Ar+H₂.
